(19) United States
(12) Patent Application Publication
(10) Pub. No.: US 2015/0295013 A1
(43) Pub. Date: Oct. 15, 2015

(54) DISPLAY DEVICE AND MANUFACTURING METHOD FOR DISPLAY DEVICE

(71) Applicant: Japan Display Inc., Tokyo (JP)

(72) Inventors: Yuko MATSUMOTO, Tokyo (JP); Toshihiro Sato, Tokyo (JP)

(21) Appl. No.: 14/686,314

(22) Filed: Apr. 14, 2015

(30) Foreign Application Priority Data
Apr. 15, 2014 (JP) 2014-083904

(51) Int. Cl. H01L 27/32; H01L 51/56; H01L 51/52

(52) U.S. Cl. CPC H01L 27/322; H01L 27/3246; H01L 51/5256; H01L 51/56; H01L 2227/323

(57) ABSTRACT

A display device includes a first substrate on which a plurality of pixel electrodes are disposed in a matrix shape, a pixel separating film provided in a convex shape to expose a part of the pixel electrodes and divide the plurality of pixel electrodes, an organic layer provided on the exposed pixel electrodes and including a light emitting layer, a counter electrode provided to be overlapped with the light emitting layer and the pixel separating film, a sealing insulating film provided on the counter electrode, and a colored layer provided to fill a region surrounded by the convex pixel separating film and to be overlapped with an upper surface of the pixel separating film.

### CROSS-REFERENCE TO RELATED APPLICATION

The present application claims priority from Japanese application JP2014-083904 filed on Apr. 15, 2014, the content of which is hereby incorporated by reference into this application.

### BACKGROUND OF THE INVENTION

1. Field of the Invention

The present invention relates to a display device and a manufacturing method for the display device.

2. Description of the Related Art

An organic electroluminescent element attracts attention as a thin and light-weight light emitting source. An organic electroluminescent display device including a large number of organic electroluminescent elements and a color filter has been developed.

As such an organic electroluminescent element, for example, JP 2008-207464 A discloses a configuration including, on a TFT substrate on which a thin film transistor is formed, a bank for dividing pixels, organic layers formed on the pixels, a cathode formed over a plurality of the pixels, and a counter substrate disposed on the cathode via a filler.

According to a demand for refining of pixels in recent years, there is a demand for a reduction in the distance between the pixels. However, as the distance between the pixels is smaller, the pixels are more easily affected by the distance between a light emitting element and a counter substrate. Therefore, when the counter substrate is mounted via the filler as described in JP 2008-207464 A, light leakage to the pixels adjacent to the counter substrate easily occurs.

In particular, when the counter substrate is a color filter substrate, light generated from the light emitting element is likely to leak to a color filter opposed to the pixels adjacent to the color filter substrate. Therefore, in an organic electroluminescent display device including a color filter substrate, it is difficult to prevent deterioration in a viewing angle involved in high definition.

### SUMMARY OF THE INVENTION

The present invention has been devised in view of such circumstances and it is an object of the present invention to realize a display device capable of preventing deterioration in a viewing angle and a manufacturing method for the display device.

Overviews of representative inventions among inventions disclosed in this application are briefly explained below.

(1) A display device according to the present invention includes: a first substrate on which a plurality of pixel electrodes are disposed in a matrix shape; a pixel separating film provided in a convex shape to expose a part of the pixel electrodes and divide the plurality of pixel electrodes; an organic layer provided on the exposed pixel electrodes and including a light emitting layer; a counter electrode provided to be overlapped with the light emitting layer and the pixel separating film; a sealing insulating film provided on the counter electrode; and a colored layer provided to fill a region surrounded by the convex pixel separating film and to be overlapped with an upper surface of the pixel separating film.

(2) A formation region of the colored layer may be larger than the pixel electrode in plan view.

(3) The sealing insulating film may be made of an inorganic material.

(4) The sealing insulating film may include a stacked structure of an inorganic material and an organic material.

(5) A manufacturing method for a display device according to the present invention includes: forming a plurality of pixel electrodes in a matrix shape above a first substrate; forming a pixel separating film provided in a convex shape to expose a part of the pixel electrodes and divide the plurality of pixel electrodes; forming, on the exposed pixel electrodes, an organic layer including a light emitting layer; forming a counter electrode to be overlapped with the light emitting layer and the pixel separating film; forming a sealing insulating film on the counter electrode; and forming a colored layer to fill a region surrounded by the convex pixel separating film and to be overlapped with an upper surface of the pixel separating film.

(6) The colored film may be formed by a printing method.

(7) The printing method may be a flexographic printing method.

According to the present invention, compared with the organic electroluminescent display device not including the configuration explained above, emitted light from a light emitting region is suppressed from being reflected on the pixel separating film and reaching pixels adjacent to the pixel separating film. Consequently, the organic electroluminescent display device of the present invention can realize suppression of color mixture.

### DESCRIPTION OF THE DRAWINGS

FIG. 1 is a schematic plan view of an organic electroluminescent display device according to an embodiment of the present invention;

FIG. 2 is a schematic sectional view taken along a II-II section line of the organic electroluminescent display device shown in FIG. 1;

FIG. 3 is a schematic sectional view showing, in a visual field same as a visual field of FIG. 2, a manufacturing method for the organic electroluminescent display device shown in FIG. 2;

FIG. 4A is a schematic sectional view showing the manufacturing method for the organic electroluminescent display device shown in FIG. 2;

FIG. 4B is a schematic sectional view showing the manufacturing method for the organic electroluminescent display device shown in FIG. 2;

FIG. 4C is a schematic sectional view showing the manufacturing method for the organic electroluminescent display device shown in FIG. 2;

FIG. 5 is a schematic sectional view showing, in a visual field same as a visual field of FIGS. 4A to 4C, the manufacturing method for the organic electroluminescent display device shown in FIG. 2; and

FIG. 6 is a partially enlarged view showing, in a visual field same as the visual field of FIGS. 4A to 4C, a modification of the manufacturing method for the organic electroluminescent display device according to the embodiment.

### DETAILED DESCRIPTION OF THE INVENTION

An organic electroluminescent display device 1, which is an example of an organic electroluminescent display device according to an embodiment, is explained below with reference to the drawings. Note that, in the drawings referred to below, characteristic portions are sometimes enlarged for convenience in order to clearly show characteristics. Dimension ratios and the like of components are not always the same as actual dimension ratios. Materials and the like illustrated in the following explanation are examples. The components may be different from the materials and the like. The present invention may be changed and carried out without changing the gist of the present invention.

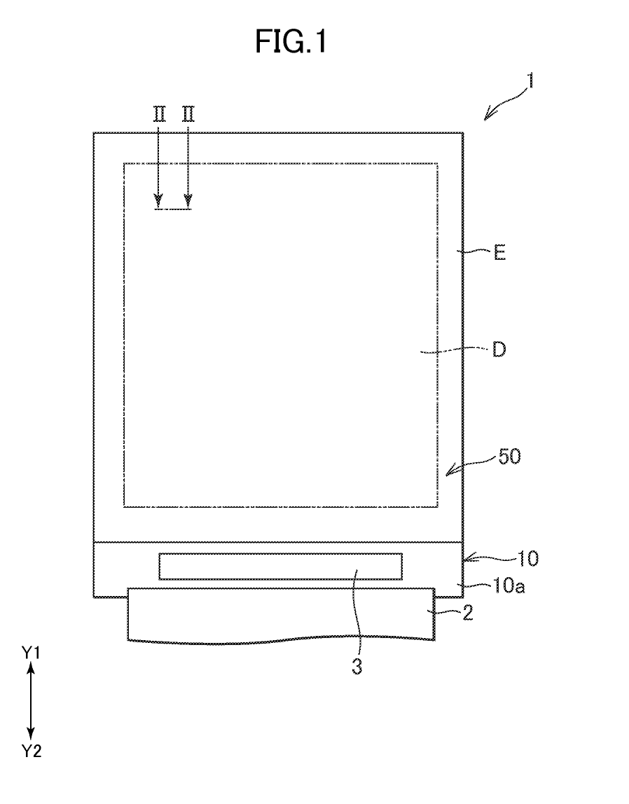

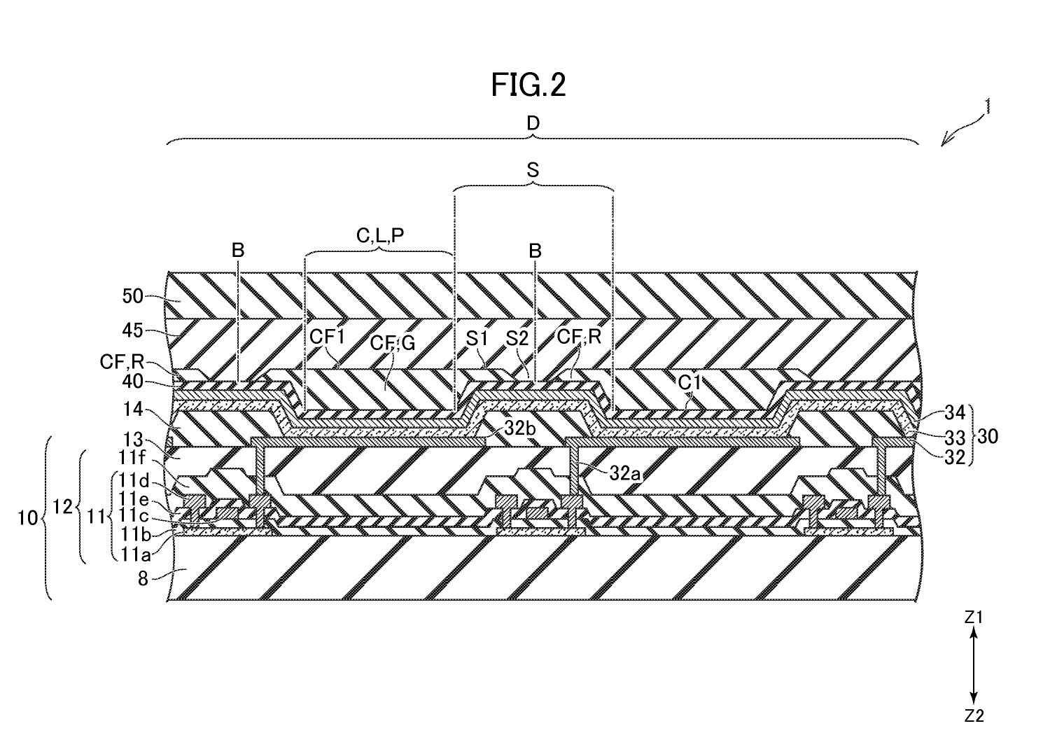

FIG. 1 is a schematic plan view of the organic electroluminescent display device 1 according to an embodiment of the present invention. FIG. 2 is a schematic sectional view taken along a II-II section line of the organic electroluminescent display device 1 shown in FIG. 1. Note that, in this embodiment, for convenience of explanation, a positional relations among components is explained using coordinates of a Y axis (a Y1 direction and a Y2 direction) and a Z axis (a Z1 direction and a Z2 direction).

As shown in FIG. 1, the organic electroluminescent display device 1 includes a TFT substrate 10 including a rectangular display region D and a counter substrate 50. A plan view shape of the TFT substrate 10 is smaller than a plan view shape of the counter substrate 50. An upper surface 10a of a part (a portion on the Y2 direction side) of the TFT substrate 10 is exposed without being covered with the counter substrate 50. A flexible wiring board 2 and a driver IC (Integrated Circuit) 3 are connected to the upper surface 10a.

Details of the configuration of the display region D of the organic electroluminescent display device 1 are explained. As shown in FIG. 2, on the TFT substrate 10 in the display region D, a plurality of pixels P are disposed in a matrix shape.

The TFT substrate 10 includes an insulating substrate 8, a circuit layer 12 in which thin film transistors 11 and not-shown electric wires are formed, and a planarizing film 13. On the TFT substrate 10, an organic electroluminescent element 30, a sealing insulating film 40, a color filter CF, a protection film 45, and the counter substrate 50 are provided.

The circuit layer 12 is formed on the insulating substrate 8. The circuit layer 12 is a layer for driving the organic electroluminescent element 30. In the circuit layer 12, the thin film transistors 11, a passivation film 11f, and the not-shown electric wires are formed.

The thin film transistors 11 are provided on the TFT substrate 10 for each of the pixels P. Specifically, the thin film transistors 11 are configured from, for example, polysilicon semiconductor layers 11a, gate insulating layers 11b, gate electrodes 11c, source drain electrodes 11d, and first insulating films 11e. The thin film transistors 11 are covered with the passivation film 11f, which is an insulating film for protecting the thin film transistors 11.

The planarizing film 13 is formed to cover the circuit layer 12. The planarizing film 13 is a layer made of an insulating material. The planarizing film 13 is formed between the circuit layer 12 and the organic electroluminescent element 30, whereby the thin film transistors 11 adjacent to one another and the thin film transistors 11 and the organic electroluminescent element 30 are electrically insulated. The planarizing film 13 is made of a material such as SiO₂, SiN, acryl, or polyimide.

Not-shown reflection films made of metal films may be formed in regions corresponding to the pixels P on the planarizing film 13. If the reflection films are provided, light emitted from the organic electroluminescent element 30 is reflected toward the counter substrate 50 side.

On the planarizing film 13 (on the TFT substrate 10), a plurality of the organic electroluminescent elements 30 are formed for each of the pixels P. The organic electroluminescent elements 30 include anodes (pixel electrodes) 32, organic layers 33 including at least light emitting layers, and cathodes (counter electrodes) 34 formed to cover the organic layers 33. Regions where the pixel electrodes 32, the organic layers 33, and the counter electrodes 34 overlap function as light emitting regions L.

The pixel electrodes 32 are electrodes that inject a driving current into the organic layers 33. Since the pixel electrodes 32 are connected to contact holes 32a, the pixel electrodes 32 are electrically connected to the thin film transistors 11 and supplied with the driving current.

The pixel electrodes 32 are made of a material having electric conductivity. Specifically, the material of the pixel electrodes 32 are preferably, for example, ITO (Indium Tin Oxide) but may be a material having translucency and electric conductivity such as IZO (indium zinc composite oxide), tin oxide, zinc oxide, indium oxide, or aluminum oxide. Note that, if the reflection films are made of metal such as silver and are in contact with the pixel electrodes 32, the pixel electrodes 32 may have translucency. In the case of such a configuration, the reflection films are a part of the pixel electrodes 32.

Among the pixel electrodes 32 adjacent to one another, pixel separating films 14 are formed along boundaries B of pixels P to divide the pixels P adjacent to one another. The pixel separating films 14 have a function of preventing contact of the pixel electrodes 32 adjacent to one another and a leak current between the pixel electrodes 32 and the counter electrodes 34.

The pixel separating films 14 in this embodiment cover outer ends 32b of the pixel electrodes 32 and project to the counter substrate 50 side (the Z1 direction side in the figure). Consequently, surfaces having an uneven shape are formed by the upper surfaces (surfaces on the Z1 direction side) of the pixel separating films 14 and the upper surfaces of the pixel electrodes 32.

The pixel separating films 14 cover the outer ends 32b of the pixel electrodes 32 and expose regions of the pixel electrodes 32 corresponding to the light emitting regions L. The pixel separating films 14 is made of an insulating material and specifically made of, for example, a photosensitive resin composition.

Note that, in this embodiment, regions corresponding to the exposed pixel electrodes 32 are referred to as concave regions C and regions on the pixel separating films 14 are referred to as convex regions S. Note that the concave regions C correspond to the light emitting regions L.

The organic layers 33 are layers including at least light emitting layers and formed of an organic material. The organic layers 33 are formed by stacking, for example, in order from the pixel electrodes 32 side, hole injection layers, hole transport layers, light emitting layers, electron transportation layers, and electron injection layers, which are not shown. Note that a stacked structure of the organic layers 33 is not limited to this structure. The stacked structure is not particularly limited as long as the stacked structure includes at least the light emitting layers.

The organic layers 33 (the light emitting layers) are formed to cover the exposed pixel electrodes 32 (the regions of the pixel electrodes 32 corresponding to the light emitting regions L) and the pixel separating films 14. Note that an emitted light color of the light emitting layers in this embodiment is white but may be other colors.

The light emitting layers are made of, for example, an organic electroluminescent substance that emits light when holes and electrons combine. Such an organic electroluminescent substance may be, for example, a substance generally used as an organic light emitting material.

The counter electrodes 34 are formed to cover the organic layers 33 (the light emitting layers) and the pixel separating films 14. The counter electrodes 34 in this embodiment are not independent for each of the pixels P and are formed to cover the entire surfaces of the regions where the pixels P are disposed in the display region D. Since the counter electrodes 34 include such a configuration, the counter electrodes 34 are in contact with the organic layers 33 of the plurality of organic electroluminescent elements 30 in common.

The counter electrodes 34 are made of a material having translucency and electric conductivity. Specifically, the material of the counter electrodes 34 is preferably, for example, ITO. However, the material of the counter electrodes 34 may be a material obtained by mixing metal such as silver or magnesium in conductive metal oxide such as ITO or InZnO or a material obtained by stacking a metal thin film of silver, magnesium, or the like and conductive metal oxide.

The upper surfaces of the counter electrodes 34 are covered with the sealing insulating film 40 over the plurality of pixels P. In the sealing insulating film 40 formed in the display region D, upper surfaces C1 of portions covering the concave regions C and upper surfaces S1 of portions covering the convex regions S form a surface having an uneven shape to trace the contours of surfaces formed by the upper surfaces (surfaces on the Z1 direction side) of the pixel separating films 14 and the upper surfaces of the pixel electrodes 32.

The sealing insulating film 40 is a film that prevents intrusion of oxygen and moisture into the layers such as the organic layers 33. The material of the sealing insulating film 40 is not particularly limited as long as the material is a transparent material having insulation properties. Note that the sealing insulating film 40 may be made of an inorganic material or may be made of an organic material. The sealing insulating film 40 may be a multilayer structure of a film made of the organic material and a film made of the inorganic material.

The color filter CF is formed on the sealing insulating film 40. The color filter CF in this embodiment includes colored films R, G, and B colored in a plurality of colors such as red, green, and blue. The colored films R, G, and B are films that allow light from the organic electroluminescent elements 30 to pass and are made of, for example, resins colored by pigments.

The colored films R, G, and B in this embodiment are formed by a printing method such as a flexographic printing method to be embedded in the sealing insulating film 40 (the upper surfaces C1) in the respective concave regions C. Therefore, the colored films R, G, and B are respectively in contact with the upper surfaces C1 of the pixels P of the sealing insulating film 40. Note that the colored films R, G, and B only have to be embedded in at least recesses of the upper surfaces C1. A part of the colored films R, G, and B may be formed on the upper surfaces S1 in the convex regions S. Formation regions of the colored films R, G, and B are larger than the pixel electrodes 32 in plan view.

With such a configuration, surfaces formed by upper surfaces CF1 of the colored films R, G, and B and surfaces S2 exposed from the colored films R, G, and B in the upper surfaces S1 have a shape closer to a flat shape than the contours of surfaces formed by the upper surfaces C1 and the upper surfaces S1.

The upper surface of the color filter CF is covered with, for example, the counter substrate 50 via the protection film 45. The material of the protection film 45 is not limited as long as the material has insulating properties. As the protection film 45, photosetting resin or an insulative sheet disposed by the printing method can be used. Note that, if the protection film 45 has the function of the counter substrate 50, the counter substrate 50 disposed on the protection film 45 can be omitted.

In the organic electroluminescent display device 1 in this embodiment, since the colored films R, G, and B are formed to be embedded in the recessed regions C, the colored films R, G, and B are disposed on the light emitting regions L of the organic electroluminescent elements 30 via only the sealing insulating film 40. Therefore, compared with the organic electroluminescent display device having the conventional configuration, the distance between the light emitting regions L and the colored films R, G, and B of the color filter CF is small.

Therefore, in the organic electroluminescent display device in this embodiment, light generated from the organic electroluminescent elements 30 is prevented from leaking to the pixels P adjacent to the organic electroluminescent elements 30. Therefore, it is possible to realize high definition and prevention of deterioration in a viewing angle of the organic electroluminescent display device 1.

In the organic electroluminescent display device 1 in this embodiment, compared with the organic electroluminescent display device not having the configuration of this embodiment, the surfaces formed by upper surfaces CF1 of the colored films R, G, and B and the surfaces S2 exposed from the colored films R, G, and B in the upper surfaces S1 have a shape closer to a flat shape than the contours of the surfaces formed by the upper surfaces C1 and the upper surfaces S1. Therefore, it is possible to reduce the thickness of the protection film 45 that covers the color filter CF.

If the protection film 45 has the function of the counter substrate 50, the counter substrate 50 disposed on the protection film 45 can be omitted. Therefore, it is possible to realize a reduction in the thickness of the organic electroluminescent display device 1.

In the organic electroluminescent display device 1 in this embodiment, the sealing insulating film 40 is made of the inorganic material. Therefore, the surfaces formed by the upper surfaces C1 and the upper surfaces S1 can be formed in a fine shape. Therefore, the shape of the colored films R, G, and B embedded in the upper surfaces C1 is also a fine shape. It is possible to realize high definition of the organic electroluminescent display device 1.

In the organic electroluminescent display device 1 in this embodiment, the protection film 45 has the multilayer structure of the film made of the organic material and the film made of the inorganic material. Therefore, it is possible to adjust the shape of the surfaces formed by the upper surfaces C1 and the upper surfaces S1 and a level difference of the upper surfaces C1 and the upper surfaces S1 from the TFT substrate 10. Therefore, it is possible to realize high definition of the organic electroluminescent display device 1.

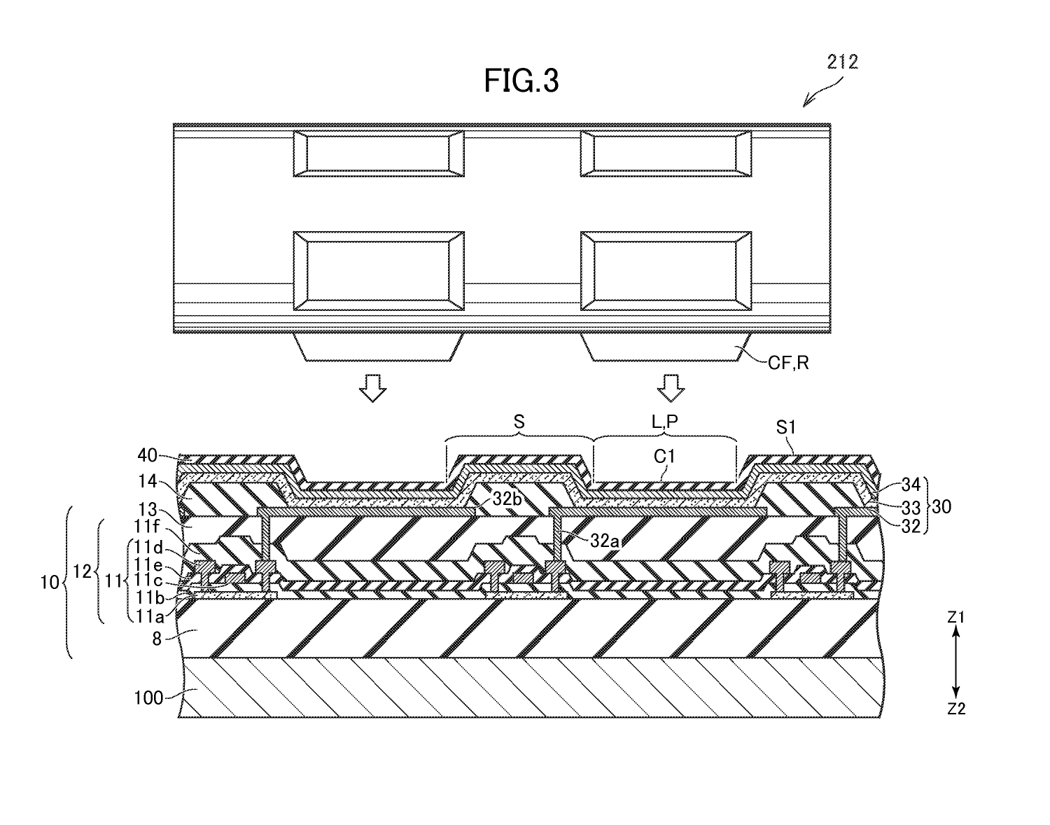

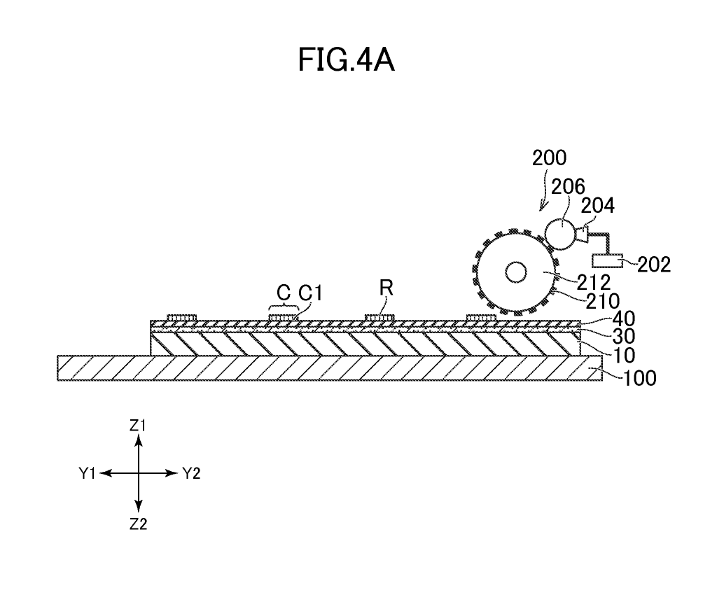

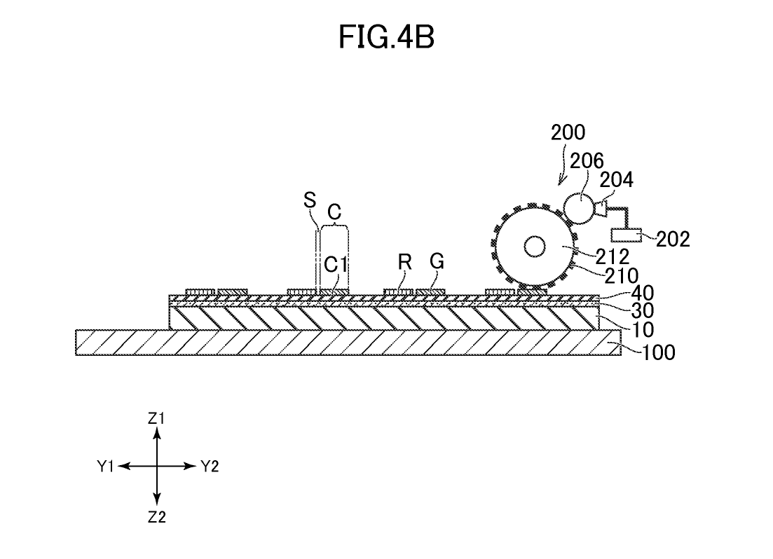

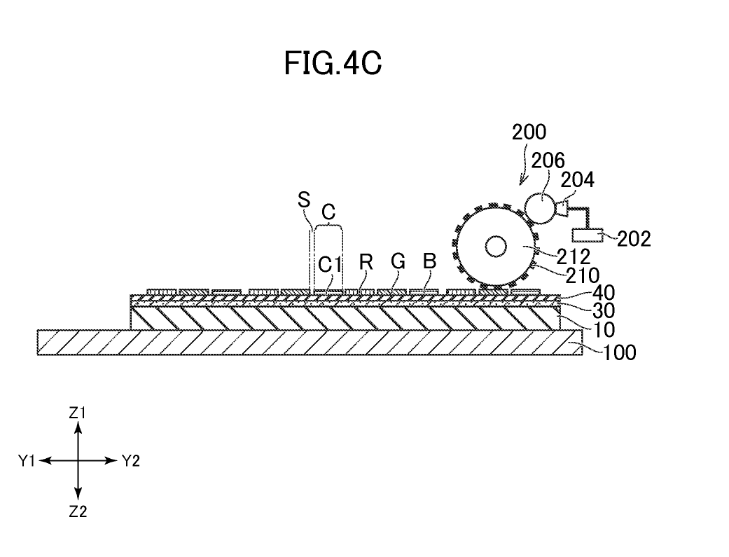

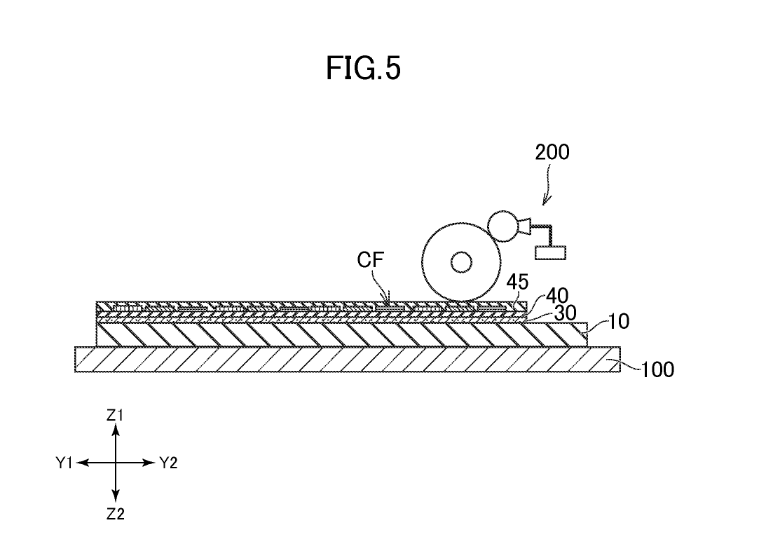

A manufacturing method for the organic electroluminescent display device 1 according to the embodiment of the present invention is explained with reference to the drawings. FIG. 3 is a schematic sectional view showing, in a visual field same as a visual field of FIG. 2, a manufacturing method for the organic electroluminescent display device 1 shown in FIG. 2. FIGS. 4A, 4B, and 4C are schematic sectional views showing the manufacturing method for the organic electroluminescent display device 1 shown in FIG. 2. FIG. 5 is a schematic sectional view showing, in a visual field same as a visual field of FIGS. 4A to 4C, the manufacturing method for the organic electroluminescent display device 1 shown in FIG. 2.

The manufacturing method for the organic electroluminescent display device 1 includes a step of preparing the TFT substrate 10, a step of forming the organic electroluminescent elements 30 on the TFT substrate 10, a step of forming the sealing insulating film 40, a step of forming the colored films R, G, and B, and a step of forming the protection film 45. Details of the steps are explained below.

First, the TFT substrate 10 on which the plurality of pixels P are disposed in a matrix shape is prepared. Note that the configuration of the TFT substrate 10 is as explained above. Detailed explanation is omitted concerning the configuration and a manufacturing method for the TFT substrate 10.

Subsequently, the organic electroluminescent elements 30 are formed on the TFT substrate 10. The step of forming the organic electroluminescent elements 30 includes a step of forming the pixel electrodes 32, a step of forming the pixel separating films 14, a step of forming light emitting layers (the organic layers 33), and a step of forming the counter electrodes 34.

First, the pixel electrodes 32 are formed on the TFT substrate 10 (the planarizing film 13). Subsequently, on the pixel electrodes 32, the pixel separating films 14 that divide the pixels P adjacent to one another to expose apart (portions corresponding to the light emitting regions L) of the pixel electrodes 32 are formed to project to the counter substrate 50 side (the Z1 direction side in the figure).

The pixel separating films 14 only has to be made of an insulting material. For example, a photosensitive resin composition can be used. Consequently, surfaces having an uneven shape are formed by the upper surfaces (surfaces on the Z1 direction side) of the pixel separating films 14 and the upper surfaces of the pixel electrodes 32. Note that, in this embodiment, regions corresponding to the exposed pixel electrodes 32 are referred to as concave regions C and regions on the pixel separating films 14 are referred to as convex regions S.

Subsequently, light emitting layers (the organic layers 33) are formed to cover the exposed pixel electrodes 32 (the upper surfaces of the pixel electrodes 32 in the light emitting regions L). The counter electrodes 34 are formed to cover the light emitting layers (the organic layers 33) and the pixel separating films 14. Consequently, the counter electrodes 34 are in contact with the organic layers 33 of the plurality of organic electroluminescent elements 30 in common.

Subsequently, the sealing insulating film 40 is formed on the counter electrode 34 to cover the concave regions C and the convex regions S. Consequently, the sealing insulating film 40 is formed to trace the contours of the surfaces formed by the upper surfaces (the surfaces on the Z1 direction side) of the pixel separating films 14 and the upper surfaces of the pixel electrodes 32. In the following explanation, in the upper surface of the sealing insulating film 40, portions that cover the concave regions C are referred to as upper surfaces C1 and portions that cover the convex regions S are referred to as upper surfaces S1.

Note that the sealing insulating film 40 may be made of an inorganic material or may be made of an organic material. The sealing insulating film 40 may be a multilayer structure of a film made of the organic material and a film made of the inorganic material.

Subsequently, the TFT substrate 10 on which the sealing insulating film 40 is formed is disposed on a substrate setting base 100. As shown in FIG. 3, the colored films R, G, and B are formed to be embedded in the concave regions C (the upper surfaces C1) of the sealing insulating film 40. As a method of forming the colored films R, G, and G, a well-known method can be used. However, it is preferable to use a printing method, in particular, a flexographic printing method.

In the manufacturing method for the organic electroluminescent display device 1 in this embodiment, by using the printing method as the method of forming the colored films R, G, and B, it is possible to simplify a formation process for the colored films R, G, and B (the color filter CF) compared with the manufacturing method for the conventional organic electroluminescent display device.

When the colored films R, G, and B are formed by the flexographic printing method, as shown in FIG. 3, materials (liquefied resins) of the colored films R, G, and B are deposited on positions corresponding to the concave regions C (the upper surfaces C1) on the surface of a flexographic printing plate 212. By pressing the flexographic printing plate 212 against the upper surface of the sealing insulating film 40 and rotating the flexographic printing plate 212, the materials of the colored films R, G, and B are transferred to be embedded in the upper surfaces C1. Thereafter, by hardening the material of the colored films R, G, and B, the colored films R, G, and B embedded in the upper surfaces C1 are formed.

An example of a method of forming three kinds of colored films R, G, and B with the flexographic printing method is explained below with reference to FIGS. 4A, 4B, and 4C. Note that, in FIGS. 4A, 4B, and 4C, for convenience of explanation, the configurations of the TFT substrate 10, the organic electroluminescent elements 30, and the sealing insulating film 40 are simplified.

A flexographic printing machine 200 shown in FIG. 4A includes, for example, an ink tank 202, an ink chamber 204, an anilox roll 206, and a plate cylinder 210 to which the flexographic printing plate 212 is attached. Colored liquefied resins for the colored films R, G, and B are stored in the ink tank 202. The liquefied resins are fed into the ink chamber 204 from the ink tank 202.

The anilox roll 206 is configured to rotate in contact with an ink supply section of the ink chamber 204 and the flexographic printing plate 212. The TFT substrate 10 is fixed on the slidable substrate setting base 100. The TFT substrate 10 moves from a printing start position (the Y1 side in the figure) to a printing end position (the Y2 side in the figure) while being adjusted in position.

Consequently, the concave regions C (the upper surfaces C1) of the sealing insulating film 40 move in contact with the flexographic printing plate 212. According to the rotation of the anilox roll 206, the liquefied resins supplied from the ink chamber 204 are uniformly retained on the surface of the anilox roll 206 and then transferred to the concave regions C (the upper surfaces C1) at uniform thickness.

In this way, first, as shown in FIG. 4A, the liquefied resin, which is the material of a first colored film R, is printed in the concave regions C (the upper surfaces C1) in predetermined places. Note that the thickness of the liquefied resin (the colored film R) only has to be set as appropriate according to the depth of the concave regions C (a level difference of the concave regions C and the convex regions S from the upper surface of the TFT substrate 10).

Similarly, as shown in FIG. 4B, the liquefied resin, which is the material of a second colored film G, is printed to be embedded in the concave regions C (the upper surfaces C1) in predetermined places. Subsequently, as shown in FIG. 4C, the liquefied resin, which is the material of a third colored film B is printed in predetermined places. Thereafter, the liquefied resins are hardened, whereby the colored films R, G, and B embedded in the upper surfaces C1 of the sealing insulating film 40 are formed.

Note that, in this embodiment, the method of forming the three kinds of colored films R, G, and B is explained as an example. However, colors of the colored films are not limited to the three colors of R, G, and B and may be a single color. As shown in FIGS. 4A to 4C, the materials of the colored films may be printed for each of different colors. However, colored films of a plurality of colors may be simultaneously printed.

Thereafter, the protection film 45 having insulating properties is formed to cover the upper surface of the color filter CF. As a method of forming the protection film 45, for example, the printing method can be used as shown in FIG. 5. The formation method for the protection film 45 is not limited to the printing method. For example, the protection film 45 having a sheet shape may be disposed to cover the upper surface of the color filter CF.

Thereafter, the counter substrate 50 is disposed on the protection film 45. Consequently, the organic electroluminescent display device 1 shown in FIG. 2 is manufactured.

In the manufacturing method for the organic electroluminescent display device 1 in this embodiment, the colored films R, G, and B (the color filter CF) are embedded in the concave regions C (the upper surfaces C1) of the sealing insulating film 40 via only the sealing insulating film 40. Therefore, compared with the manufacturing method for the conventional organic electroluminescent display device, it is possible to reduce the distance between the light emitting regions L of the organic electroluminescent elements 30 and the color filter CF.

Therefore, it is possible to manufacture the organic electroluminescent display device 1 in which light generated from the organic electroluminescent elements 30 is suppressed from leaking to the pixels P adjacent to the organic electroluminescent elements 30 and high definition and prevention of deterioration in a viewing angle are realized.

In this embodiment, the colored films R, G, and B (the color filter CF) are embedded in the concave regions C (the upper surfaces C1) of the sealing insulating film 40. Consequently, as shown in FIG. 2, the surfaces formed by upper surfaces CF1 of the colored films R, G, and B and the surfaces S2 exposed from the colored films R, G, and B in the upper surfaces S1 can be formed in a shape closer to a flat shape than the contours of the surfaces formed by the upper surfaces C1 and the upper surfaces S1. Therefore, in this embodiment, it is possible to reduce the thickness of the protection film 45 that covers the color filter CF. It is possible to manufacture the thin organic electroluminescent display device 1.

In the manufacturing method for the organic electroluminescent display device 1 in this embodiment, the flexographic printing method is used as the method of forming the colored films R, G, and B. Consequently, it is possible to simplify the formation process for the colored films R, G, and B (the color filter CF) compared with the manufacturing method for the conventional organic electroluminescent display device.

By using the flexographic printing method, since the colored films R, G, and B can be embedded in the fine pixels P, it is possible to form the high-definition color filter CF. Therefore, it is possible to manufacture the high-definition organic electroluminescent display device 1.

By using the flexographic printing method, as shown in FIG. 2, the surfaces formed by upper surfaces CF1 of the colored films R, G, and B and the surfaces S2 exposed from the colored films R, G, and B in the upper surfaces S1 can be formed in a shape closer to a flat shape than the contours of the surfaces formed by the upper surfaces C1 and the upper surfaces S1.

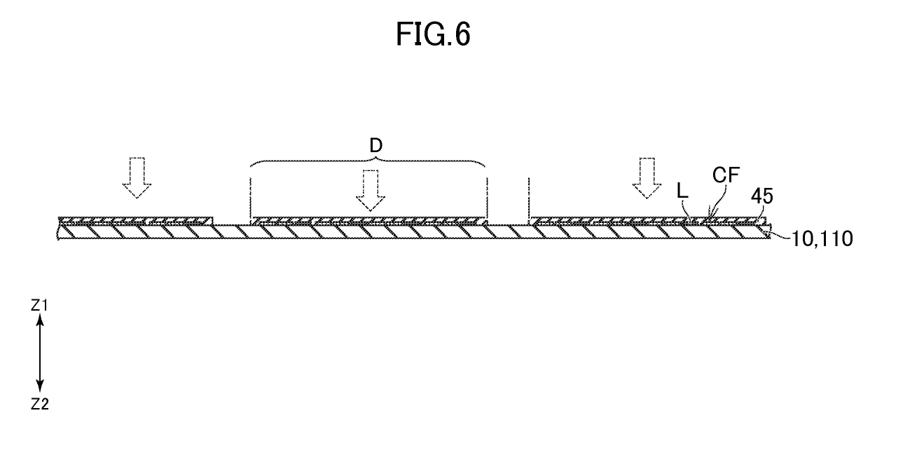

Note that the manufacturing method for the organic electroluminescent display device 1 in this embodiment is not limited to the method explained above. Other methods may be used. FIG. 6 is a partially enlarged view showing, in a visual field same as the visual field of FIGS. 4A to 4C, a modification of the manufacturing method for the organic electroluminescent display device 1 according to this embodiment. Note that, in FIG. 6, for convenience of explanation, the organic electroluminescent elements 30 and the sealing insulating film 40 are not shown.

For example, as in the example shown in FIG. 6, the protection film 45 having function of a counter substrate may be formed by disposing photosetting resin in the region corresponding to the display region D of the TFT substrate 10.

Specifically, such a protection film 45 can be formed by irradiating UV light on resin applied to the display region D of the TFT substrate 10 (a mother board 110). In this embodiment, the colored films (the color filter CF) are formed to cover the upward direction (the Z1 direction in the figure) of the light emitting regions L. Therefore, even in the method for irradiating the UV light in this way, it is possible to suppress deterioration in the organic layers 33 due to the irradiation of the UV light.

In this embodiment, by manufacturing the protection film 45 having the functions of the counter substrate in this way, it is possible to omit the counter substrate 50 disposed on the protection film 45. Therefore, it is possible to manufacture the thinner organic electroluminescent display device 1.

A process for sticking the counter substrate on the protection film 45 and thereafter singulating the counter substrate is unnecessary. Therefore, foreign matters are suppressed from being caught between the counter substrate and the TFT substrate 10. Therefore, it is possible to manufacture the organic electroluminescent display device 1 having high reliability.

An organic electroluminescent display device, which is an example of the present invention, may include: a TFT substrate on which a plurality of pixels are disposed in a matrix shape; a pixel electrode formed on the TFT substrate; a pixel separating film provided on the pixel electrode to divide the pixels adjacent to one another and configured to expose a part of the pixel electrode; a light emitting layer configured to cover the exposed pixel electrode; a counter electrode configured to cover the light emitting layer and the pixel separating film; a sealing insulating film configured to cover a concave region, which is a region corresponding to the exposed pixel electrode, and a convex region, which is a region on the pixel separating film, on the counter electrode; and a colored film formed to be embedded in the concave regions of the sealing insulating film.

A manufacturing method for an organic electroluminescent display device, which is another example of the present invention, may include: forming a pixel electrode on a TFT substrate on which a plurality of pixels are disposed in a matrix shape; forming, on the pixel electrode, a pixel separating film that divides the pixels adjacent to one another to expose a part of the pixel electrode; forming a light emitting layer to cover the exposed pixel electrode; forming a counter electrode to cover the light emitting layer and the pixel separating film; forming, on the counter electrode, a sealing insulating film to cover a concave region, which is a region corresponding to the exposed pixel electrode, and a convex region, which is a region on the pixel separating film; and forming a colored film to be embedded in the concave region of the sealing insulating film.

While there have been described what are at present considered to be certain embodiments of the invention, it will be understood that various modifications may be made thereto, and it is intended that the appended claims cover all such modifications as fall within the true spirit and scope of the invention.

What is claimed is:

1. A display device comprising:
a first substrate on which a plurality of pixel electrodes are disposed in a matrix shape;
a pixel separating film provided in a convex shape to expose a part of the pixel electrodes and divide the plurality of pixel electrodes;
an organic layer provided on the exposed pixel electrodes and including a light emitting layer;
a counter electrode provided to be overlapped with the light emitting layer and the pixel separating film;
a sealing insulating film provided on the counter electrode; and
a colored layer provided to fill a region surrounded by the convex pixel separating film and to be overlapped with an upper surface of the pixel separating film.

2. The display device according to claim 1, wherein a formation region of the colored layer is larger than the pixel electrode in plan view.

3. The display device according to claim 1, wherein the sealing insulating film is made of an inorganic material.

4. The display device according to claim 1, wherein the sealing insulating film includes a stacked structure of an inorganic material and an organic material.

5. A manufacturing method for a display device comprising:
forming a plurality of pixel electrodes in a matrix shape above a first substrate;
forming, a pixel separating film provided in a convex shape to expose a part of the pixel electrodes and divide the plurality of pixel electrodes;
forming, on the exposed pixel electrodes, an organic layer including a light emitting layer;
forming a counter electrode to be overlapped with the light emitting layer and the pixel separating film;
forming a sealing insulating film on the counter electrode; and
forming a colored layer to fill a region surrounded by the convex pixel separating film and to be overlapped with an upper surface of the pixel separating film.

6. The manufacturing method for the display device according to claim 5, wherein the colored film is formed by a printing method.

7. The manufacturing method for the display device according to claim 6, wherein the printing method is a flexographic printing method.
